(19) United States
(12) Patent Application Publication
(10) Pub. No.: US 2026/0033385 A1
(43) Pub. Date: Jan. 29, 2026

(54) HUMIDITY SENSOR AND INTEGRATED CIRCUIT INCLUDING SAME

(71) Applicant: Taiwan Semiconductor Manufacturing Company, LTD., Hsinchu (TW)

(72) Inventors: Kang-Tai Peng, Zhubei (TW); Yi-Cheng Chiu, Taipei (TW); Wei-Kuan Yen, Hsinchu (TW); Hsi-Cheng Hsu, Taichung (TW)

(21) Appl. No.: 18/784,081

(22) Filed: Jul. 25, 2024

(51) Int. Cl. H01L 25/07; G01N 27/22; H01L 29/06; H01L 29/40

(52) U.S. Cl. CPC H01L 25/072; G01N 27/223; H10D 62/103; H10D 64/112

(57) ABSTRACT

An integrated circuit (IC) includes electronic components monolithically disposed on and/or in a semiconductor substrate, the electronic components including at least a humidity sensor device, a metallization stack, and an exposed conductive surface that is electrically connected with the humidity sensor device by the metallization stack of the IC. The exposed conductive surface is exposed to an ambient gas whose relative humidity is to be measured. In some designs, the humidity sensor device includes a PN junction, and the exposed conductive surface is electrically connected with the cathode of the PN junction. The exposed conductive surface may be an exposed bond pad of the IC.

### BACKGROUND

The following relates to the humidity sensing arts, the semiconductor fabrication arts, integrated circuit (IC) arts, and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a side sectional view of a humidity sensor device.

FIG. 2 diagrammatically illustrates the side sectional view of the humidity sensor device as shown in FIG. 1, further illustrating electrical connections thereto in accordance with one suitable connection configuration, and further diagrammatically illustrating an exposed conductive surface that is electrically connected with the humidity sensor device by a metallization stack of an IC.

FIG. 3 diagrammatically plots expected trendlines for breakdown voltage and leakage current of a humidity sensor device designed as disclosed herein.

FIG. 4 diagrammatically illustrates the side sectional view of the humidity sensor device as shown in FIG. 1, further illustrating electrical connections thereto in accordance with another suitable connection configuration.

FIG. 5 diagrammatically illustrates a top view of a humidity sensor device having an annular layout.

FIG. 6 diagrammatically illustrates a top view of a humidity sensor device having a linear layout.

FIG. 7 diagrammatically illustrates a top view of an integrated circuit (IC) including a humidity sensor.

FIG. 8 diagrammatically illustrates a top view of an integrated circuit including the exposed conductive surface configured to be exposed to an ambient gas whose relative humidity is to be measured.

FIG. 9 diagrammatically illustrates a side sectional view of a humidity sensor device according to another embodiment and electrical connections thereto.

FIG. 10 diagrammatically illustrates a side sectional view of a humidity sensor device according to another embodiment and electrical connections thereto.

FIG. 11 diagrammatically illustrates a side sectional view of a humidity sensor device integrated with a high voltage MOSFET.

FIGS. 12A, 12B, 12C, 12D, 12E, 12F, and 12G diagrammatically illustrate, by way of successive side sectional views, fabrication of a humidity sensor device.

FIG. 13 is a flowchart of an IC fabrication process which includes monolithically fabricating a humidity sensor device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Disclosed herein are embodiments of a humidity sensor comprising a PN junction, in which the humidity sensor operates based on electric field modification due to humidity-dependent accumulation of OH⁻ ionized gas on an electrical conductor (for example, an exposed bond pad) connected with a cathode of the PN junction. In some nonlimiting illustrative embodiments, the sensing of humidity is based on humidity dependence of the breakdown voltage and/or leakage current of a reverse biased PN junction that is reverse biased at a high voltage (e.g., 400V or higher in some nonlimiting illustrative embodiments), and which has an exposed bond pad with an exposed surface that is exposed to the air or other ambient gas whose relative humidity is to be measured. The N-type region of the PN junction is electrically connected with the exposed bond pad so that the applied high voltage is present at the exposed bond pad, so that OH⁻ ions can accumulate on the pad due to the high voltage. Readout circuitry of the humidity sensor in some such nonlimiting illustrative embodiments is configured to output an electrical signal indicative of a relative humidity of the ambient gas based on a breakdown voltage and/or a leakage current of the reverse-biased PN junction. As disclosed herein, there is a direct relationship between the relative humidity of the ambient gas and the leakage current of the reverse-biased PN junction, insofar as the leakage current increases with increasing relative humidity. There is an inverse relationship between the relative humidity of the ambient gas and a breakdown voltage of the reverse-biased PN junction, insofar as the breakdown voltage decreases with increasing relative humidity.

Also disclosed herein are nonlimiting illustrative embodiments of an integrated circuit (IC) that advantageously includes such a humidity sensor monolithically integrated with other electronic components such as field effect transistors. Notably, a capacitive humidity sensor based on a metal-oxide-metal plate structure with a porous metal film is challenging to integrate with an IC, as the porous metal film fabrication is not a common step in IC fabrication processes. By contrast, humidity sensors as disclosed herein utilize P-type and N-type regions forming a PN junction, and can be fabricated using common steps of IC fabrication processes such as photolithographically controlled dopant implantation, thermal oxidation, and so forth, thus enabling monolithic integration of a humidity sensor into an IC as disclosed herein.

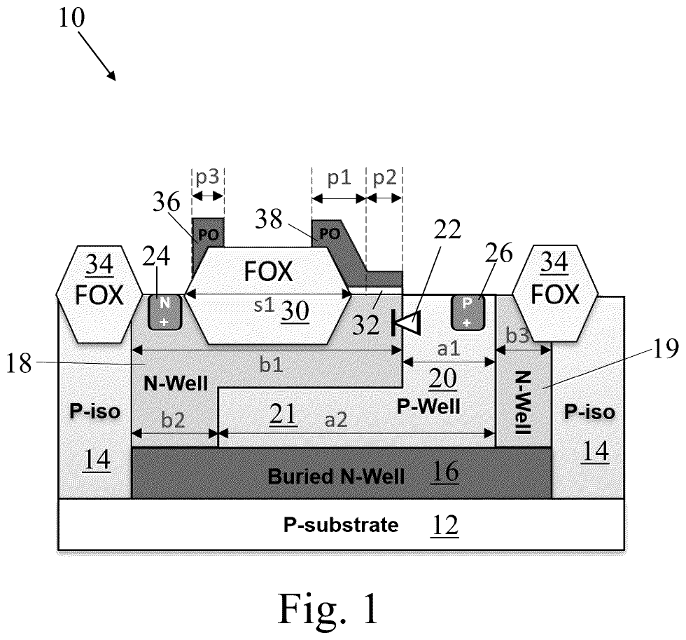

With reference to FIG. 1, a humidity sensor device 10 according to a nonlimiting illustrative embodiment is diagrammatically illustrated by side sectional view. The humidity sensor device 10 is fabricated on a P-type substrate 12. In some nonlimiting illustrative examples, the substrate 12 is a P-type silicon substrate. P-type isolation (P-iso) regions 14 together with the P-type substrate form a P-type container within which an N-type container is disposed, including a buried N-type well (buried N-well) 16 and a N-type (e.g., N-well) regions 18 and 19. The humidity sensor device 10 further includes P-type (e.g. P-well) regions 20 and 21.

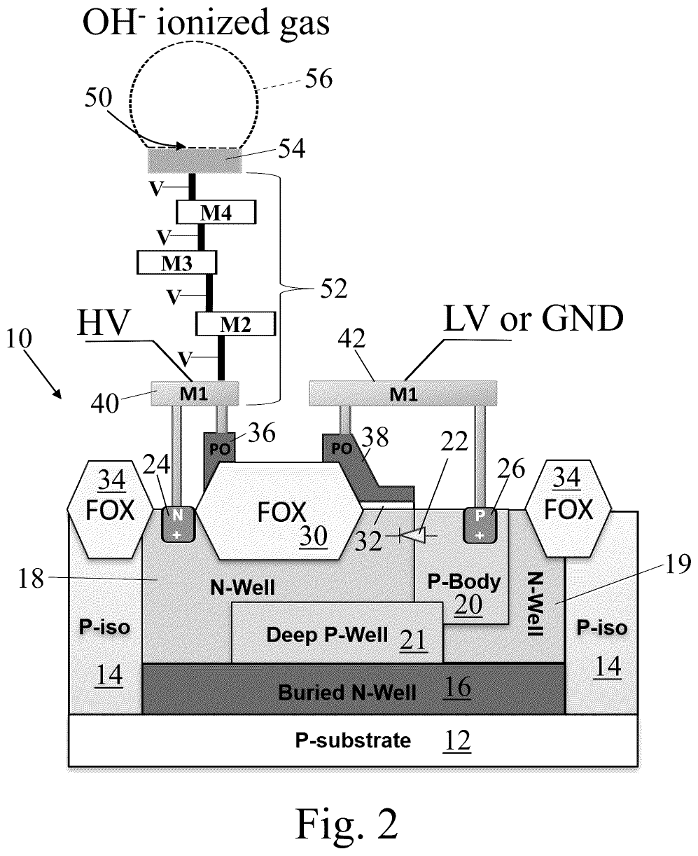

In FIG. 1 the two P-type areas 20 and 21 are illustrated as contiguous; however, in some other embodiments, the two P-type regions 20 and 21 may be distinguishable in terms of doping levels or other characteristics. For example, the region 21 may be a deep P-well 21 formed by a first photolithographically controlled P-type dopant implantation step, and a shallower P-type body region 20 may be formed by a second photolithographically controlled P-type dopant implantation step, potentially with different P-type doping concentration. (For comparison, FIG. 2 illustrates an example where the two areas of the P-type region 20, 21 are diagrammatically distinguished). Furthermore, in some embodiments the two N-type regions 18 and 19 may be initially formed as a single N-type region by a single N-type dopant implantation step, and subsequent P-type counter-doping to form the P-type region 20 then separates the two N-type regions 18 and 19.

The humidity sensor device 10 thus includes an N-type region 18, and a P-type region 20 disposed relative to the N-type region 18 to form a PN junction 22 (where the PN junction 22 is diagrammatically indicated in FIG. 1 by a diode symbol). A more highly doped N⁺ contacting region 24 is embedded in the N-type region 18. The N⁺ contacting region 24 may also be referred to herein as an N⁺-type source region 24, or for brevity as source region 24 or source 24. A more highly doped P⁺ region 26 is embedded in the P-type region 20, forming a P⁺-type contacting region 26. The P⁺-type contacting region 26 may also be referred to herein as a P⁺-type drain region 26, or for brevity as drain region 26 or drain 26. These highly doped regions 24 and 26 facilitate forming ohmic (or approximately ohmic) contacts to the N-side 18 and P-side 20 of the PN junction 22, respectively.

In some contemplated embodiments, the doped regions 14, 16, 18, 19, 20, 21, 24, and 26 may be doped silicon regions, e.g. using suitable N-type dopants for silicon such as arsenic, phosphorous, or antimony as nonlimiting illustrative examples for the N-type regions; and using suitable P-type dopants for silicon such as boron or aluminum as nonlimiting illustrative examples for the P-type regions. However, it is also contemplated for the humidity sensor device 10 to be fabricated in another material system such as silicon-germanium, gallium arsenide (GaAs), or so forth, and in such cases the doped regions 14, 16, 18, 19, 20, 21, 24, and 26 are made of a suitable material or materials for that system.

With continuing reference to FIG. 1, the humidity sensor device 10 optionally further includes one or more oxide layers or regions, e.g., an illustrative field oxide (FOX) 30 and/or an illustrative gate oxide 32. For silicon-based devices, the oxide layers or regions 30 and 32 may be silicon dioxide. These oxide layers 30, 32 facilitate forming a field plate for modifying (e.g., optimizing) the electric field in the PN junction 22. Additional field oxide 34 (e.g., additional silicon dioxide regions) may be disposed on the P-type isolation 14 for further active area delineation. The field oxide regions 30 and 34 may in some embodiments be formed in a single oxidation step followed by patterning. One or more gates 36, 38 disposed on the oxide 32 and/or 34 complete the field plate. In the illustrative example, a (first) gate 36 is disposed on the field oxide 30 in a region proximate to the N-type source region 24, and a (second) gate 38 is disposed at least on the gate oxide 32 (and also extending onto the field oxide 30 in the illustrative example). The gate(s) 36, 38 may, for example, comprise polysilicon, although other materials with suitable conductivity and material compatibility are contemplated. It is further noted that the illustrative field plate formed by the illustrative elements 30, 34, 36, and 38 are a nonlimiting illustrative example, and more generally the field plate can have other suitable configurations, or in some embodiments a field plate may be omitted entirely.

FIG. 1 further depicts certain dimensions. Without being limited to any particular size constraints, some nonlimiting illustrative value ranges for these dimensions are provided here. A width a1 of a top portion of P-well 20 indicated in FIG. 2 may be in a range of 30 μm ≥a1≥0.05 μm. A width a2 of a bottom portion of P-well 21 may be in a range of 30 μm≥a2≥0.5 μm. A width b1 of a top portion of N-well 18 may be in a range of 30 μm≥b1≥0.5 μm. A width b2 of a bottom portion of N-well 18 may be in a range of 30 μm≥b2≥0.1 μm. A width b3 of a peripheral N-well 19 may be in a range of 30 μm≥b3≥0.05 μm. A space s1 of the field oxide 30 may be in a range of 200 μm≥s1≥1 μm. A width p1 of a bevel part of the gate 38 disposed on the field oxide 30 may be in a range of 15 μm≥p1≥0.05 μm. A width p2 of a flat part of the gate 38 disposed on the gate oxide 32 may be in a range of 10 μm≥p2≥0.05 μm. A width p3 of the gate 36 disposed on the field oxide 30 proximate to the N-type source region 24 may be in a range of 30 μm≥p3≥0.05 μm. Again, these are nonlimiting illustrative example dimension ranges, and values outside of these respective ranges are also contemplated.

With reference now to FIG. 2, the side sectional view of the humidity sensor device 10 of FIG. 1 is again diagrammatically shown, along with further illustration of electrical connections to the humidity sensor device 10 in accordance with one suitable connection configuration. Initially, it is noted that the side sectional view of the humidity sensor device 10 of FIG. 2 differs from that of FIG. 1 in that FIG. 2 illustrates the two P-type areas 20 and 21 as distinguished. As previously mentioned, the region 21 may be a deep P-well 21 formed by a first photolithographically controlled P-type dopant implantation step, and a shallower P-type body region 20 may be formed by a second photolithographically controlled P-type dopant implantation step, potentially with different P-type doping concentration.

In the nonlimiting illustrative example of FIG. 2, the electrical connections of the humidity sensor device 10 include a high voltage connection 40 (also labeled “HV” in FIG. 2) that connects with the N-type region 18 by way of the N⁺-type contacting region 24, and a low voltage connection 42 (also labeled “LV or GND” in FIG. 2) that connects with the P-type region 20 by way of the P⁺-type contacting region 26. As indicated by the “HV” and “LV or GND” labels of the respective connections 40 and 42), the PN junction 22 of the humidity sensor device 10 is reverse biased during operation of the humidity sensor device 10.

For example, the high voltage connection 42 may connect with a high voltage source (not shown), e.g. 400 volts or higher in some non-limiting illustrative examples; while the low voltage connection 42 connects with electrical ground (GND) producing a reverse bias of at least 400 volts across the PN junction 22 (neglecting any voltage drops across the N-type region 18 and across the P-type region 20). The low voltage connection 42 can instead connect with a low but non-ground voltage which is substantially lower than the high voltage applied to the high voltage terminal 40. For example, if the humidity sensor device 10 is integrated with an IC that includes a 5 volt or 3.3 volt digital power supply, the low voltage connection 42 can connect with this low voltage power supply. These are nonlimiting illustrative examples.

As further diagrammatically illustrated in FIG. 2, an exposed conductive surface 50 is electrically connected with the humidity sensor device 10 by a metallization stack 52 which includes patterned metal layers and vias interconnecting the patterned metal layers. In the diagrammatic representation of FIG. 2, the metallization stack 52 has patterned metal layers denoted as patterned metal layers M1, M2, M3, M4, . . . embedded in a dielectric material (not shown, sometimes referred to as intermetal dielectric or “IMD”) and connected by vias V. In FIG. 2, the patterned metal layer M1 is disposed closest to the humidity sensor device 10, and successive patterned metal layers M2, M3, M4, . . . are located progressively further away from the humidity sensor device 10. In embodiments in which the humidity sensor device 10 is integrated as an electronic component of an integrated circuit (IC), the humidity sensor device 10 may be fabricated along with other electronic components of the IC (for example, along with field effect transistors of the IC) during front end-of-line (FEOL) processing, and the metallization stack 52 may be the metallization stack of the IC formed during back end-of-line (BEOL) processing. The patterned metal layers M2, M3, M4, . . . may, for example, comprise copper layers or other suitably electrically conductive layers. The vias V may comprise tungsten or another suitably electrically conductive material. The intermetal dielectric material may, for example, comprise silicon oxide, fluorinated silica glass (FSG), carbon doped silicon oxide, tetra-ethyl-ortho-silicate (TEOS) formed oxide, phosphosilicate glass (PSG), or borophosphosilicate glass (BPSG), as some nonlimiting illustrative examples. It will be appreciated that FIG. 2 diagrammatically shows the metallization stack 52 by depicting portions of the patterned metal layers M1, M2, M3, M4, . . . and connecting vias V that implement the electrical connection of the exposed conductive surface 50 with the humidity sensor device 10. The high voltage connection 40 comprises (the portion of) the patterned metal layer M1 in the illustrative example.

The exposed conductive surface 50 is exposed to an ambient gas whose relative humidity is to be measured (or sensed). In many applications, the ambient gas is the ambient atmosphere; however, the ambient gas could more generally be any ambient gas that contains water vapor whose concentration can be quantified by relative humidity. In the illustrative example, the exposed conductive surface 50 is disposed at an upper surface of the metallization stack 52 (e.g., a metallization stack of an IC with which the humidity sensor device 10 is monolithically integrated), and the exposed conductive surface 50 is electrically connected with the N-type region 18 of the humidity sensor device 10 by the metallization stack 52. In some embodiments, the exposed conductive surface 50 is an exposed surface of a bonding pad 54 formed at the top of the metallization stack 52.

The reverse bias applied to the PN junction 22 via the high voltage connection 40 produces a positive voltage at the exposed conductive surface 50. In some embodiments, the high voltage for reverse biasing the PN junction 22 is applied to the exposed conductive surface 50, for example by way of a wire bond, bonding bump, or other electrical conductor that is bonded to the bonding pad 54 whose exposed surface constitutes the exposed conductive surface 50 in the illustrative example. The high voltage applied to the exposed conductive surface 50 thus produces the desired positive voltage (e.g., 400V or higher in some nonlimiting illustrative embodiments), and also applies that high voltage to the N-type region 18 of the PN junction 22.

However, the high voltage need not be applied at the exposed conductive surface 50. As another example, the high voltage could be applied at the patterned metal layer M3, so that the PN junction 22 is reverse biased by way of the conductive path running from patterned metal layer M3 through vias V to patterned metal layer M2, patterned metal layer M1, and thence to the N-type region 18 forming the cathode of the PN junction 22. The high voltage applied at the patterned metal layer M3 (in this nonlimiting illustrative example) also produces a positive voltage at the exposed conductive surface 50 by way of the conductive path running from patterned metal layer M3 through vias V to patterned metal layer M4 and thence to the bonding pad 54 which includes the exposed conductive surface 50.

As recognized herein, a humidity sensor is provided by the humidity sensor device 10 with the reverse biased PN junction 22 having its cathode (i.e., N-type region 18) connected with an exposed conductive surface 50 that is exposed to the ambient gas whose humidity is to be measured. The working principle of the humidity sensor is based on additional electric field induced by accumulation of (diagrammatically indicated) OH⁻ ionized gas 56 collecting on or proximate to the exposed conductive surface 50 due to the high voltage produced at that surface 50. The additional electric field is proportional to relative humidity of the ambient gas to which the exposed conductive surface 50 is exposed, and thus one or more electrical characteristics of the PN junction 22 are modified in a manner that depends on relative humidity of the ambient gas.

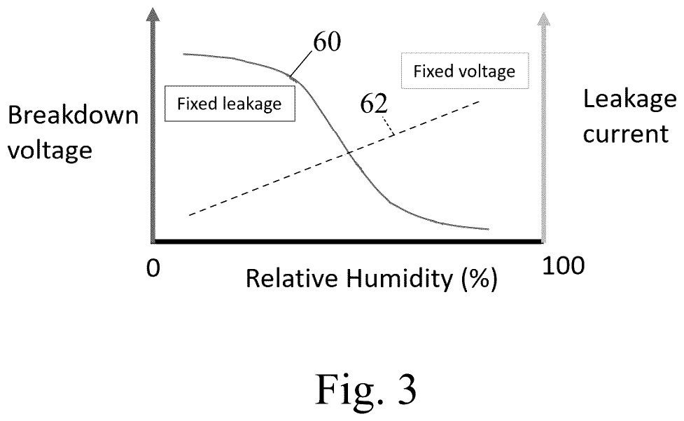

With reference to FIG. 3, a plot 60 is shown of expected breakdown voltage (BV) versus relative humidity (%). As is diagrammatically shown, an inverse relationship exists between the relative humidity (RH) of the ambient gas and measured breakdown voltage (BV) of the reverse-biased PN junction 22 of the humidity sensor device 10. Such an inverse relationship has been experimentally verified, with a decrease in BV observed from around 850 volts at RH of about 20%, down to a BV of about 600 volts at RH of about 48%. In a suitable implementation of a humidity sensor, readout circuitry (for example, comprising a subset of the electronic components such as field effect transistors of an IC with which the humidity sensor device 10 is monolithically integrated) are configured with a constant current circuit to maintain a fixed leakage current, and to output an electrical signal (e.g., a voltage or a current) corresponding to the BV that is indicative of RH of the ambient. The output electrical signal may be a current or voltage measured at the low voltage connection 42, or may be derived therefrom, in some nonlimiting illustrative examples.

With continuing reference to FIG. 3, a plot 62 is shown of expected leakage current versus relative humidity (%). As is diagrammatically shown, a direct relationship is expected between the relative humidity (RH) of the ambient gas and measured leakage current of the reverse-biased PN junction 22 of the humidity sensor device 10. In a suitable implementation of a humidity sensor, readout circuitry (for example, comprising a subset of the electronic components such as field effect transistors of an IC with which the humidity sensor device 10 is monolithically integrated) are configured to apply a fixed reverse bias voltage, and to output an electrical signal (e.g., a voltage or a current) corresponding to the leakage current that is indicative of RH of the ambient gas. The output electrical signal may be a current or voltage measured at the low voltage connection 42, or may be derived therefrom, in some nonlimiting illustrative examples.

It is also contemplated for the readout circuitry of the humidity sensor to measure the relative humidity based on both BV and leakage current. In some embodiments, the electrical signal output by the readout circuitry that is indicative of RH of the ambient gas may be digitized, and converted to a digital signal directly proportional to RH using a look-up table, empirical transform, or so forth.

For the one or more electrical characteristics (e.g., BV or leakage current) of the PN junction 22 to be modified in a manner that depends on relative humidity of the ambient gas, the high voltage applied to reverse bias the PN junction 22 should be sufficiently high to produce sufficient electric field to collect OH⁻ ionized gas 56 (see FIG. 2) on or proximate to the exposed conductive surface 50 so as to produce a measurable change in the one or more electrical characteristics. In experimental tests, it was found that 400 volts or higher was sufficient for this purpose. However, the minimum voltage that will be sufficient may be higher or lower than this value, depending on factors such as the area of the exposed conductive surface 50, the range of relative humidity to be measured, the type of ambient gas being monitored (e.g., its composition, pressure, et cetera), and the particular structure of the humidity sensor device being used.

As previously noted, a field plate (e.g., the field plate formed by the illustrative elements 30, 34, 36, and 38 in the illustrative example of FIGS. 1 and 2) may be used to optimize the performance of the humidity sensor. In the illustrative example of FIG. 2, the connection 42 forms an electrical short connecting the P-type region 20 and the gate 38. This results in the humidity sensor device 10 comprising a diode with two terminals, with high voltage terminal 40 being applied to the cathode of the PN diode 22 to provide the reverse bias and the low voltage terminal providing the output.

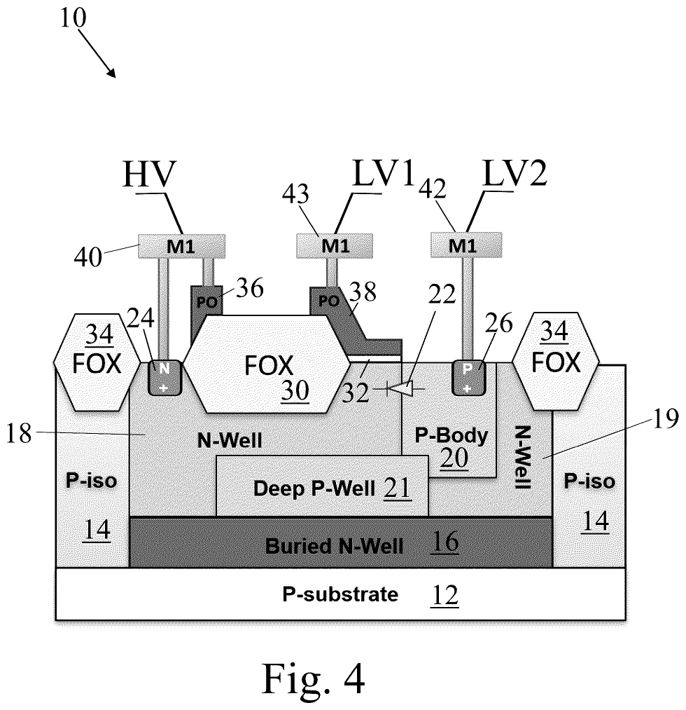

With reference now to FIG. 4, the side sectional view of the humidity sensor device 10 as shown in FIG. 1 is again reproduced, and further diagrammatically illustrated are electrical connections to the humidity sensor device 10 in accordance with another suitable connection configuration. The embodiment of FIG. 4 differs from that of FIG. 2 in that the electrical short connecting the P-type region 20 and the gate 38 in the embodiment of FIG. 2 is replaced by a low voltage or ground connection 42 to the P-type region 20 and a separate gate connection 43 to the gate 38. The gate connection 43 thus provides an additional input that can be used to tune the performance of the humidity sensor by optimizing the electric field in the vicinity of the PN junction 22. Optimal voltages (possibly including electrical ground) to apply to the connections 42 and 43 can be empirically co-optimized using a grid search, since there are only two inputs being varied. If the high voltage applied to the high voltage connection 40 is also included in the optimization, a three-parameter grid search optimization is still readily conducted to co-optimize all three inputs.

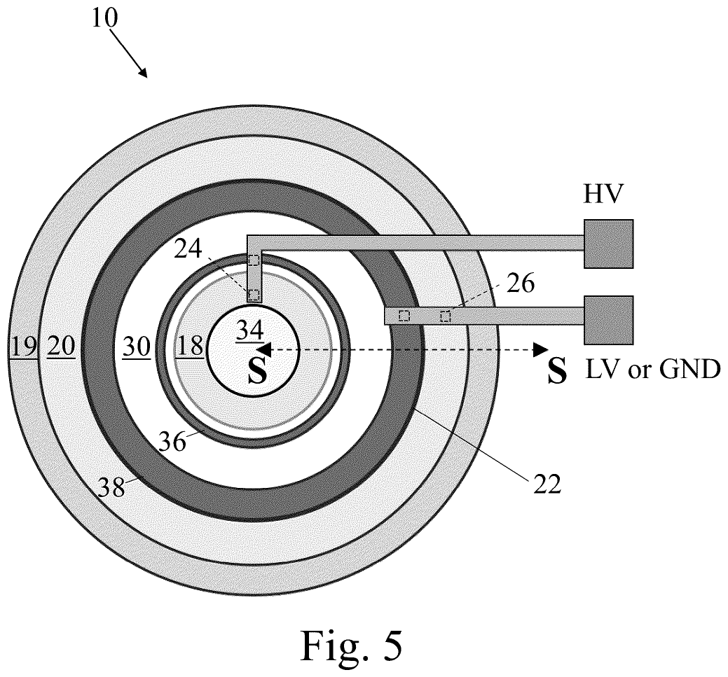

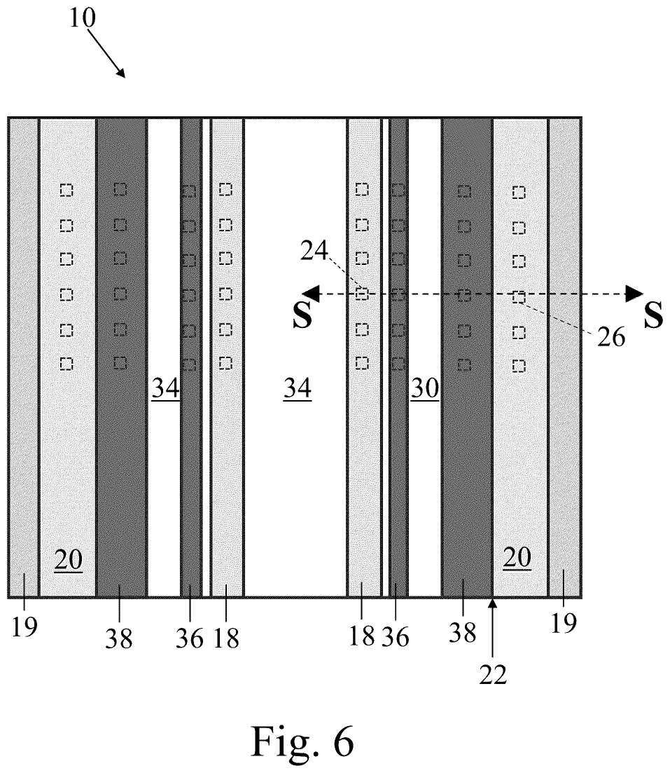

With reference back now to FIGS. 1 and 2, and with further reference to FIGS. 5 and 6, the humidity sensor device 10 can have various layouts. FIG. 5 illustrates a top view of the humidity sensor device 10 having a two-dimensional (2D) layout, and FIG. 6 illustrates a top view of the humidity sensor device 10 having a one-dimensional (1D) linear layout. A section line S-S is indicated in each of FIGS. 5 and 6, which corresponds to the side sectional view shown in FIG. 1. (Note that the rightmost P-isolation region 14 and field oxide 34 shown in FIG. 1 are not shown in the top views).

In the 2D layout of FIG. 5, the portions visible in the top (i.e. plan) view are as follows: field oxide 34 is centrally located, surrounded by the N-type region 18, surrounded by the field oxide 34 with the gates 36 and 34 disposed on annular portions thereof, with the P-type region 20 surrounding the radially outer gate 38, and the N-type region 19 forming the radially outermost portion shown in FIG. 5. The PN junction 22 as indicated in FIG. 5 is located at about the boundary between the outer radius of the gate 38 and the visible portion of the P-type region 20. Note that while FIG. 5 illustrates a rotationally symmetric 2D configuration for the humidity sensor device 10, other 2D layouts could be analogously implemented, such as a square layout, a rectangular layout, a hexagonal (six-fold symmetric) layout, an octagonal (eight-fold symmetric) layout, or so forth.

In the 1D layout of FIG. 6, the portions visible in the top (i.e. plan) view are arranged linearly in the following order: field oxide 34, N-type region 18, field oxide 34 (with the gates 36 and 34 disposed on strips thereof), P-type region 20, and N-type region 19. The PN junction 22 as indicated in FIG. 6 is located at about the boundary between the gate 38 and the visible portion of the P-type region 20.

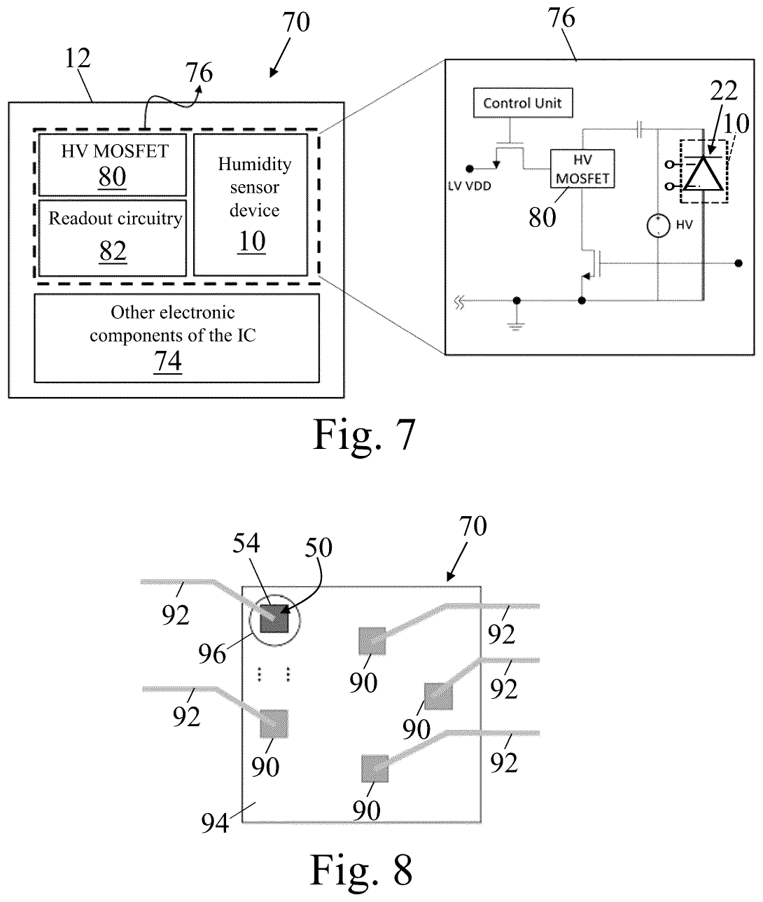

With reference now to FIG. 7, an integrated circuit (IC) 70 is shown, fabricated on a semiconductor substrate 12 (see also FIGS. 1 and 2) which may for example be a silicon substrate, a silicon-on-insulator (SOI) substrate, a silicon-germanium substrate, a gallium arsenide (GaAs) substrate, or so forth. The IC 70 includes electronic components 10, 76, 78, 80 monolithically disposed on and/or in a semiconductor substrate 12. The electronic components 10, 76, 80, 82 may, for example, include field effect transistors, diodes, and/or so forth 74, that perform various functions for which the IC 70 is designed; and the electronic components monolithically disposed on and/or in a semiconductor substrate 12 further includes the humidity sensor 76. In the illustrative example, the humidity sensor 76 includes a humidity sensor device 10, e.g., in accordance with embodiments thereof previously described with reference to FIGS. 1-6, or further embodiments of humidity sensor devices described later herein). The humidity sensor 76 further includes bias circuitry, such as an illustrative high voltage MOSFET 80, configured to reverse bias the PN junction 22 of the humidity sensor device 10. As previously noted, this reverse bias also produces a positive high voltage at the exposed conductive surface 50 (see FIG. 2). The humidity sensor 76 further includes readout circuitry 82 configured to output an electrical signal indicative of a relative humidity of the ambient gas, for example based on a breakdown voltage and/or a leakage current of the reverse-biased PN junction 22 as previously described with reference to FIGS. 2 and 3.

It is noted that the layout of the electronic components (or groups of electronic components) 10, 74, 80, 82 shown for the IC 70 in FIG. 7 is diagrammatic, and the physical layout may be organized to meet various practical and/optimization criteria. For example, it is sometimes beneficial to group the high voltage electronics (e.g., operating at 100 volts or higher in some nonlimiting examples) in one or a few designated “high voltage” regions of the IC layout, and to group digital circuitry or other low voltage circuitry (e.g., operating at 5 volts or less for some digital circuitry families) in other “low voltage” regions of the IC layout, so as to avoid having the high voltages adversely impact performance of the low voltage circuitry. In such physical layouts, the humidity sensor device 10 and HV MOSFET 80 (and more generally the bias circuitry) of the humidity sensor 76 is suitably located in the HV region(s), while the readout circuitry 82 of the humidity sensor 76 may be located in the HV region(s) and/or the LV region(s) depending on the voltages employed in the readout circuitry 82 (or in portions thereof). The right side of FIG. 7 diagrammatically shows a high-level circuit diagram including some principal components of the humidity sensor 76, including the humidity sensor device 10 and its PN junction 22, the HV MOSFET 80 connected to reverse bias the PN junction 22, and ancillary biasing circuity for controlling the reverse bias voltage.

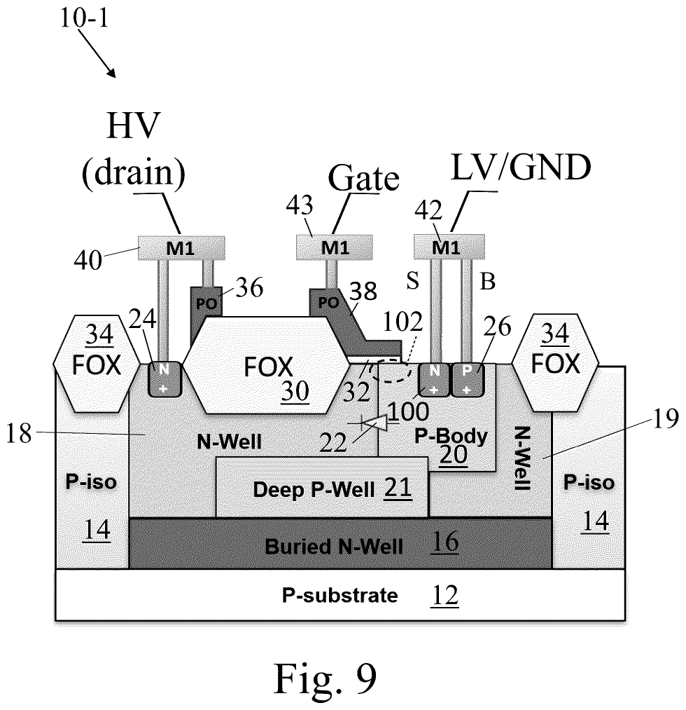

With reference to FIG. 8, a top (i.e., plan) view is diagrammatically shown of the IC 70, including the exposed conductive surface 50 configured to be exposed to the ambient gas whose relative humidity is to be measured. In this example, the IC 70 includes a plurality of bond pads 90 which are contacted by respective conductors 92, such as wire bonds, bonding bumps of a ball grid array (BGA), or so forth. One of the bond pads is the bond pad 54 previously discussed with reference to FIG. 2, which as shown in FIG. 2 is electrically connected with the humidity sensor device 10 by the metallization stack 52 of the IC. The bond pads 90 and 54 may, for example, be aluminum or aluminum alloy bond pads, though other electrically conductive materials are contemplated. After the electrical contacts 92 are made, a molding compound 94 is disposed over the surface of the IC 70 to seal the surface to prevent ingress of moisture into the IC, including via interfaces around the bond pads 90. However, as shown in FIG. 8, the applied molding compound 94 has an opening 96 that exposes the exposed conductive surface 50 of the bond pad 54 which is electrically connected with the humidity sensor device 10 by the metallization stack 52. This ensures that the exposed conductive surface 50 is exposed to the ambient air (or, more generally, to the ambient gas) whose relative humidity is to be measured, thus enabling the OH⁻ ionized gas 56 (see FIG. 2) to collect on or proximate to the exposed conductive surface 50 due to the high voltage produced at that surface 50.

Optionally, the conductor 92 connecting with the bond pad 54 which is electrically connected with the humidity sensor device 10 by the metallization stack 52 may also supply the high voltage (e.g., 400 volts or higher in some embodiments) to reverse bias the PN junction 22. However, as previously discussed with reference to FIG. 2 this is not necessarily the case (e.g., the requisite high voltage could be supplied via the patterned metal layer M3 of the metallization stack 54, as previously discussed with reference to FIG. 2). In this latter case, the conductor 92 connecting with the bond pad 54 may optionally be omitted.

In the embodiment of FIG. 8, the opening 56 is larger than the area of the bond pad 54, which advantageously maximizes the exposed conductive surface 50 to maximize sensitivity to humidity of the humidity sensor 76. However, in other embodiments the opening may be smaller than the area of the bond pad 54, which may reduce sensitivity but can reduce the likelihood of detrimental water ingress via the interface around the bond pad 54.

Moreover, while in the illustrative example of FIG. 8 the exposed conductive surface 50 is an exposed conductive surface of bond pad 54, the exposed conductive surface 50 could be a different exposed conductive surface, for example, a dedicated metal strip that is exposed to the ambient gas.

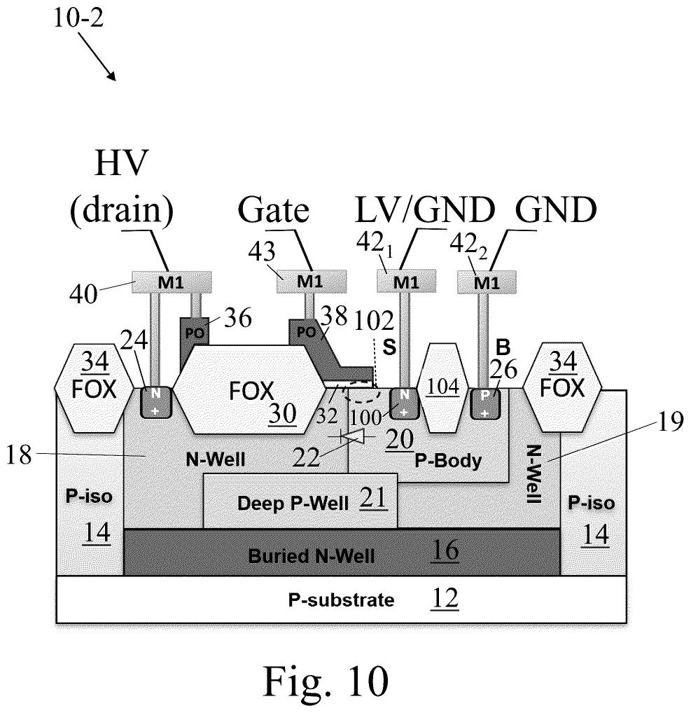

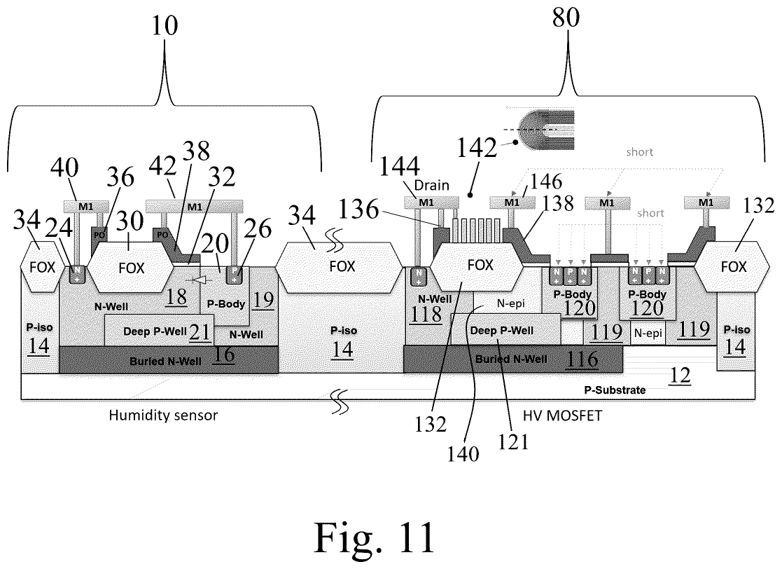

With reference now to FIGS. 9 and 10, some further nonlimiting illustrative embodiments of the humidity sensor device 10 are described. Except where otherwise noted below, corresponding reference numbers between FIG. 9 or FIG. 10 and FIGS. 1 and 2 correspond to same-numbered elements of the humidity sensor device 10 of FIGS. 1 and 2.

In FIG. 9, a humidity sensor device 10-1 is modified compared with the humidity sensor device 10 of FIGS. 1 and 2 in that the gate oxide 32 and gate 38 are extended to cover a portion of the P-type region 20, and a counter-doped N⁺ region 100 is formed in the P-type region 20. The humidity sensor device 10-1 thus has a MOSFET structure, and the portion of the P-type region 20 covered by the extension of the gate oxide 32 and gate 38 forms a P-type channel 102. The humidity sensor device 10-1 can not only achieve high breakdown voltage (BV), but as a MOSFET structure can also be used to trigger a logic circuit of the readout circuitry, depending on terminal signals.

In FIG. 10, a humidity sensor device 10-2 is further modified compared with the humidity sensor device 10-1 of FIG. 9 in that the counter-doped N⁺ region 100 and the P⁺-type drain region 26 are separated by field oxide 104. This provides isolation between source and bulk with independent terminals 421 and 422, thereby providing further control to tailor performance of the humidity sensor device 10-2.

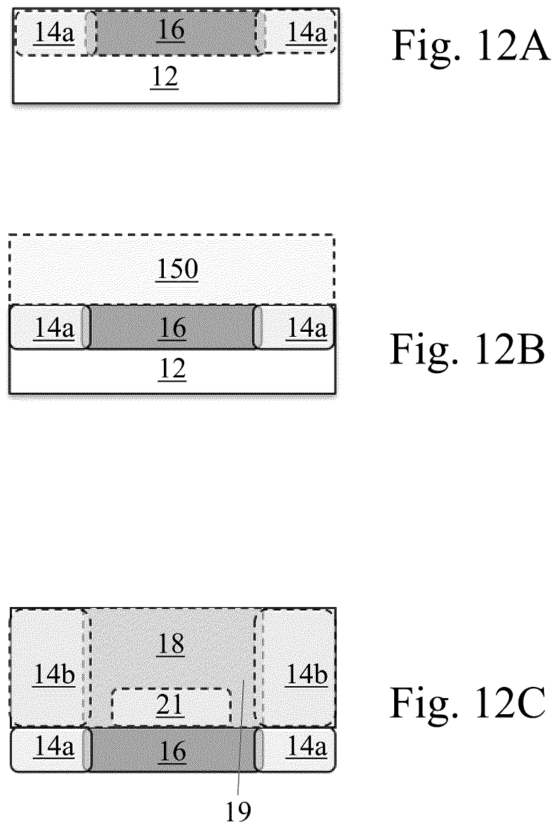

With reference to FIG. 11, a side sectional view diagrammatically illustrates the humidity sensor device 10 of FIGS. 1 and 2, integrated with the high voltage MOSFET 80 previously discussed with reference to FIG. 7. The two devices 10 and 80 are monolithically fabricated in a single IC 70 on a common substrate 12. The humidity sensor device 10 has been previously described with reference to FIGS. 1 and 2, and FIG. 11 uses the same reference numbers as in FIGS. 1 and 2 which are not described again here. The MOSFET 80 includes a buried N-well 116 which may optionally be fabricated in the same fabrication steps that form the buried N-well 16 of the humidity sensor device 10. The MOSFET 80 includes N-well regions 118 and 119 which may optionally be fabricated in the same fabrication steps that form the N-well regions 18 and 19 of the humidity sensor device 10. The MOSFET 80 includes a deep P-well region 121 which may optionally be fabricated in the same fabrication steps that form the deep P-well region 21 of the humidity sensor device 10. The MOSFET 80 includes P-well body regions 120 which may optionally be fabricated in the same fabrication steps that form the P-well body region 20 of the humidity sensor device 10. The MOSFET 80 further includes N⁺ and P⁺ contact regions which may optionally be doped or counter-doped in the same doping steps used to form the N⁺ and P⁺ contact regions 24 and 26 of the humidity sensor device 10. The MOSFET 80 further includes field oxide regions 132 which may optionally be fabricated in the same fabrication steps that form the field oxide regions 32 and 34 of the humidity sensor device 10. The MOSFET 80 further includes gates 136 and 138 which may optionally be fabricated in the same fabrication steps that form the gates 36 and 38 of the humidity sensor device 10. The MOSFET 80 further includes an additional n-type epitaxial region 140 that is formed by an additional one or more steps including epitaxial deposition, e.g. of silicon or silicon germanium as nonlimiting illustrative examples. The MOSFET 80 further includes an additional spiral polymer structure 142 with a fixed pitch (as illustrated in an inset top view of the spiral polymer structure 142), and connected with the drain side of the MOSFET 80 to create a smooth electric field from a drain 144 to a polymer gate 146 of the MOSFET 80. It will be appreciated that FIG. 11 merely illustrates one nonlimiting example of how the humidity sensor device 10 (or, similarly, the humidity sensor device 10-1 of FIG. 9 or the humidity sensor device 10-2 of FIG. 10) can be monolithically integrated with other electronic components in an IC.

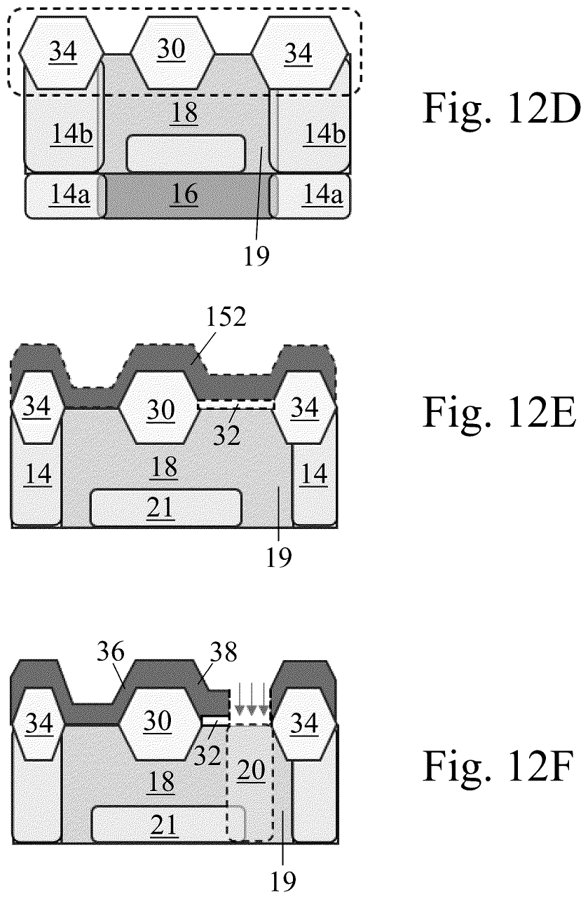

With reference now to FIGS. 12A-12G, fabrication of the humidity sensor device of FIG. 2 is diagrammatically illustrated by way of successive side sectional views.

FIG. 12A shows a cross sectional view of the humidity sensor device 10 under fabrication, after photolithographically controlled dopant implantation operations performed to form the buried N-type well 16 and lower portions 14a of the P-type isolation regions 14 (see FIG. 2).

FIG. 12B shows a cross sectional view of the humidity sensor device 10 under fabrication, after an epitaxial deposition of an N-type semiconductor layer 150 (e.g., an N-type silicon layer 150) on the structures 14a, 14b, and 16.

FIG. 12C shows a cross sectional view of the humidity sensor device 10 under fabrication, after photolithographically controlled dopant implantation operations performed to form the deep P-well 21, the N-type well 18 (and also the N-type well 19, not shown in FIG. 12C), and upper portions 14b of the P-type isolation regions 14 (see FIG. 2).

FIG. 12D shows a cross sectional view of the humidity sensor device 10 under fabrication, after active area definition including thermal oxidation and patterning to define the field oxide regions 30 and 34.

FIG. 12E shows a cross sectional view of the humidity sensor device 10 under fabrication, after formation of the gate oxide 32, e.g., by thermal oxidation and photolithographically controlled etching, and deposition of the polysilicon layer 152 which is destined to be etched to define the polysilicon gates 36 and 38.

FIG. 12F shows a cross sectional view of the humidity sensor device 10 under fabrication, after photolithographically controlled etching and dopant implantation to form the P-type body region 20.

FIG. 12G shows a cross sectional view of the humidity sensor device 10 after photolithographic etching of the polysilicon layer 152 to define the polysilicon gates 36 and 38, and formation of the highly doped N⁺ contacting region 24 embedded in the N-type region 18 by photolithographically controlled N-type dopant implantation, and formation of the highly doped P⁺ contacting region 26 embedded in the P-type region 20 by photolithographically controlled P-type dopant implantation.

It is to be appreciated that the fabrication sequence described with reference to FIGS. 12A-12G is merely a nonlimiting illustrative example, and other fabrication sequences are contemplated.

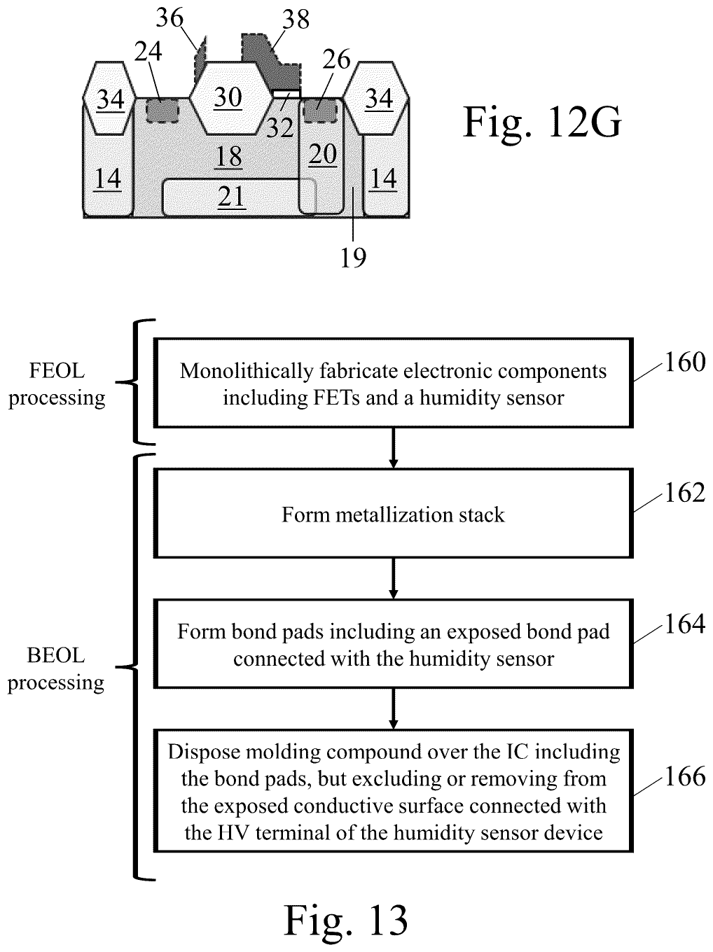

With reference to FIG. 13, a flowchart of an IC fabrication process is shown, which includes monolithically fabricating a humidity sensor device. In an operation 160 corresponding to front end-of-line (FEOL) processing, electronic components are monolithically fabricated, including field effect transistors (FET's) and the humidity sensor 10 (or, alternatively, the humidity sensor 10-1 or 10-2). For example, the operation 160 can entail the fabrication steps described with reference to FIGS. 12A-12G. Advantageously, many of these fabrication steps correspond to fabrication steps used in fabrication of many types of field effect transistors, such as photolithographically controlled dopant implantation steps, thermal oxidation to create regions of field oxide, and so forth. Hence, monolithic fabrication of the humidity sensor 10 during formation of field effect transistors and other electronic components of the IC may mostly or entirely entail minor modifications to the IC FEOL processing such as modifications of the windows in various photomasks used in the FEOL processing.

The subsequent operations 162, 164, and 166 may be classified as back end-of-line (BEOL) processing. In an operation 162, the metallization stack is formed, such as the metallization stack 52 diagrammatically shown in FIG. 2. Referring back to FIG. 2, the operation 162 may entail deposition of a layer of intermetal dielectric, photolithographic etching and metal deposition to form vias V, deposition of a blanket metal layer and photolithographic patterning thereof to form the first patterned metal layer (e.g., patterned metal layer M1 of FIG. 2), and repeating this sequence to build the metallization stack 50 by adding each subsequent patterned metal layer M2, M3, M4, . . . and the interconnecting vias V.

In an operation 164, bond pads are formed on the metallization stack, including an exposed bond pad connected with the humidity sensor 10. Referring to FIG. 8, this entails forming the previously described bond pads 54 and 90, for example by deposition of an aluminum layer on the metallization stack and photolithographically controlled etching of the aluminum layer.

In an operation 166, molding compound is disposed over the IC including the bond pads 90, but excluding (or removing) the molding compound from the exposed conductive surface connected with the HV terminal of the humidity sensor device (e.g., forming the opening 96 to expose the exposed contact pad 54).

It is to be appreciated that the fabrication sequence described with reference to FIGS. 13 is merely a nonlimiting illustrative example, and other IC fabrication sequences that include monolithic fabrication of the humidity sensor device 10 are contemplated.

In the following, some further embodiments are described.

In a nonlimiting illustrative embodiment, an integrated circuit (IC) comprises: electronic components monolithically disposed on and/or in a semiconductor substrate, the electronic components including at least field effect transistors and a humidity sensor device; a metallization stack comprising patterned metal layers embedded in a dielectric material and vias interconnecting the patterned metal layers and the electronic components; and an exposed conductive surface that is electrically connected with the humidity sensor device by the metallization stack of the IC. The exposed conductive surface is exposed to an ambient gas whose relative humidity is to be measured.

In a nonlimiting illustrative embodiment, a method of fabricating an IC comprises: monolithically fabricating electronic components on and/or in a semiconductor substrate, the electronic components including at least field effect transistors and a humidity sensor device including an N-type region and a P-type region in which the P-type and N-type regions form a PN junction; forming a metallization stack comprising patterned metal layers embedded in a dielectric material and vias interconnecting the patterned metal layers and the electronic components; and forming an exposed conductive surface on the metallization stack which is connected to the N-type region of the humidity sensor device by the metallization stack. The exposed conductive surface is exposed to an ambient gas.

In a nonlimiting illustrative embodiment, a semiconductor device comprises: a humidity sensor device including a PN junction; an exposed conductive surface connected to a cathode of the PN junction of the humidity sensor device, the exposed conductive surface being exposed to an ambient gas; bias circuitry configured to reverse bias the PN junction of the humidity sensor device wherein the reverse bias produces a positive voltage at the exposed conductive surface; and readout circuitry configured to output an electrical signal indicative of a relative humidity of the ambient gas based on a breakdown voltage and/or a leakage current of the reverse-biased PN junction of the humidity sensor device.

In a nonlimiting illustrative embodiment, an IC includes electronic components monolithically disposed on and/or in a semiconductor substrate, the electronic components including at least a humidity sensor device, a metallization stack, and an exposed conductive surface that is electrically connected with the humidity sensor device by the metallization stack of the IC. The exposed conductive surface is exposed to an ambient gas whose relative humidity is to be measured. In some designs, the humidity sensor device includes a PN junction, and the exposed conductive surface is electrically connected with the cathode of the PN junction. The exposed conductive surface may be an exposed bond pad of the IC.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes. substitutions, and alterations herein without departing from the spirit and scope of the present disclosure.

What is claimed is:

1. An integrated circuit (IC) comprising:
electronic components monolithically disposed on and/or in a semiconductor substrate, the electronic components including at least field effect transistors and a humidity sensor device;
a metallization stack comprising patterned metal layers embedded in a dielectric material and vias interconnecting the patterned metal layers and the electronic components; and
an exposed conductive surface that is electrically connected with the humidity sensor device by the metallization stack of the IC, the exposed conductive surface being exposed to an ambient gas whose relative humidity is to be measured.

2. The IC of claim 1, wherein the humidity sensor device includes:
an N-type region; and
a P-type region disposed relative to the N-type region to form a PN junction;
wherein the exposed conductive surface is disposed at an upper surface of the metallization stack of the IC and is electrically connected with the N-type region of the humidity sensor device by the metallization stack of the IC.

3. The IC of claim 1, further comprising:
bias circuitry comprising a subset of the electronic components configured to reverse bias the PN junction of the humidity sensor device wherein the reverse bias produces a positive voltage at the exposed conductive surface.

4. The IC of claim 3, further comprising:
readout circuitry comprising a subset of the electronic components configured to output an electrical signal indicative of a relative humidity of the ambient gas based on a breakdown voltage and/or a leakage current of the reverse-biased PN junction.

5. The IC of claim 4, wherein the readout circuitry is configured to output the electrical signal based on at least an inverse relationship between the relative humidity of the ambient gas and a breakdown voltage of the reverse-biased PN junction of the humidity sensor device.

6. The IC of claim 4, wherein the readout circuitry is configured to output the electrical signal based on at least a direct relationship between the relative humidity of the ambient gas and the leakage current of the reverse-biased PN junction of the humidity sensor device.

7. The IC of claim 3, wherein the humidity sensor device further includes:
a field plate comprising an oxide disposed at least on the N-type region of the humidity sensor device and a gate disposed on the oxide.

8. The IC of claim 1, including:
a high voltage region comprising a first subset of the electronic components configured to operate with a first input voltage, the first subset of the electronic components including the humidity sensor device; and
a low voltage region comprising a second subset of the electronic components configured to operate with a second input voltage that is lower than the first input voltage.

9. The IC of claim 8, wherein the first input voltage is at least 400 volts and the second input voltage is 20 volts or lower.

10. A method of fabricating an integrated circuit (IC), the method comprising:
monolithically fabricating electronic components on and/or in a semiconductor substrate, the electronic components including at least field effect transistors and a humidity sensor device including an N-type region and a P-type region in which the P-type and N-type regions form a PN junction;
forming a metallization stack comprising patterned metal layers embedded in a dielectric material and vias interconnecting the patterned metal layers and the electronic components; and
forming an exposed conductive surface on the metallization stack which is connected to the N-type region of the humidity sensor device by the metallization stack, the exposed conductive surface being exposed to an ambient gas.

11. The method of claim 10, further comprising:
forming bond pads on the metallization stack, wherein the exposed conductive surface is an exposed surface of a bond pad which is connected to the N-type region of the humidity sensor device by the metallization stack; and
disposing a molding compound over the bond pads except that the molding compound does not completely cover the exposed surface of the bond pad which is connected to the N-type region of the humidity sensor device by the metallization stack.

12. A semiconductor device comprising:
a humidity sensor device including a PN junction;
an exposed conductive surface connected to a cathode of the PN junction of the humidity sensor device, the exposed conductive surface being exposed to an ambient gas;
bias circuitry configured to reverse bias the PN junction of the humidity sensor device wherein the reverse bias produces a positive voltage at the exposed conductive surface; and
readout circuitry configured to output an electrical signal indicative of a relative humidity of the ambient gas based on a breakdown voltage and/or a leakage current of the reverse-biased PN junction of the humidity sensor device.

13. The semiconductor device of claim 12, wherein the bias circuitry produces said positive voltage being at least 400 volts at the exposed conductive surface.

14. The semiconductor device of claim 12, wherein:
the humidity sensor device is monolithically fabricated as part of an integrated circuit (IC), and a metallization stack of the IC connects the exposed conductive surface with the cathode of the PN junction of the humidity sensor device, the metallization stack of the IC comprising patterned metal layers embedded in a dielectric material and vias interconnecting the patterned metal layers and the electronic components.

15. The semiconductor device of claim 14, wherein the IC is a silicon-based IC, and the PN junction of the humidity sensor device is a silicon PN junction.

16. The semiconductor device of claim 12, wherein the humidity sensor device comprises a diode including the PN junction.

17. The semiconductor device of claim 12, wherein the humidity sensor device comprises a MOSFET including the PN junction.

18. The semiconductor device of claim 12, wherein the humidity sensor device further includes a field plate arranged to modify an electric field in the PN junction.

19. The semiconductor device of claim 12, wherein the readout circuitry is configured to output the electrical signal based at least on an inverse relationship between the relative humidity of the ambient gas and the breakdown voltage of the reverse-biased PN junction of the humidity sensor device.

20. The semiconductor device of claim 12, wherein the readout circuitry is configured to output the electrical signal based at least on a direct relationship between the relative humidity of the ambient gas and the leakage current of the reverse-biased PN junction of the humidity sensor device.
